(19) United States
(12) Patent Application Publication
(10) Pub. No.: US 2009/0184413 A1
(43) Pub. Date: Jul. 23, 2009

(54) INSULATIVE WIRING BOARD, SEMICONDUCTOR PACKAGE USING THE SAME, AND METHOD FOR PRODUCING THE INSULATIVE WIRING BOARD

(76) Inventors: Kazuaki TATSUMI, Sakurai-shi (JP); Yoshiki SOTA, Nara-shi (JP)

Correspondence Address: NIXON & VANDERHYE, PC, 901 NORTH GLEBE ROAD, 11TH FLOOR, ARLINGTON, VA, 22203, US

(21) Appl. No.: 12/212,089

(22) Filed: Sep. 17, 2008

(30) Foreign Application Priority Data
Sep. 25, 2007 (JP) 2007-247553

(51) Int. Cl. H01L 23/498; H05K 1/05; H01L 21/50

(52) U.S. Cl. 257/698; 174/255; 438/125; 257/E21.499; 257/E23.06

(57) ABSTRACT

The insulative wiring board of the present invention, with its both surfaces being covered with solder resist, includes at least one via hole in a semiconductor chip-mounting area penetrating the insulative wiring board, wherein conductor layers are electrically connected to each other via said at least one via hole. Further, the mounting area is covered with the solder resist, excluding said at least one via hole that penetrates the insulative wiring board. Therefore, it is possible to achieve an insulative wiring board that prevents defects caused by expansion occurred due to heating of moisture absorbed by the board, as well as reducing an area where a wiring cannot be provided.

This Nonprovisional application claims priority under 35 U.S.C. § 119(a) on Patent Application No. filed in Japan on Sep. 25, 2007, the entire contents of which are hereby incorporated by reference.

### FIELD OF THE INVENTION

The present invention relates to an insulative wiring board, in particular, to an insulative wiring board for preventing defects caused by vaporization and expansion occurred due to heating of absorbed moisture. The present invention also relates to a semiconductor package using the insulative wiring board, and to a method for producing the insulative wiring board.

### BACKGROUND OF THE INVENTION

CSPs (Chip Size Packages/Chip Scale Packages) of QFP (Quad Flat Package) type, BGA (Ball Grid Allay) type, and LGA (Land Grid Array) type and the like have recently been prevailing among other semiconductor packages.

In especial, the semiconductor package of recent years has been required for semiconductor elements to be highly integrated and for signal processing to be carried out at a high speed. In view of the circumstances, out of the types, the semiconductor packages of resin-sealing type such as the BGA type and the LGA type are particularly in wide use. This is because these types of the semiconductor package have a structure in which a semiconductor chip, with its surface on which a circuit is formed so as to face upward, is connected to a wiring board by a thin metal wire and is electrically connected to an external connection terminal via a wiring pattern so that a greater number of external terminals can be provided.

In addition, an insulative wiring board used in the semiconductor package has been highly required to be thinner in thickness. An insulative core substrate, made of epoxy resin, having a thickness of 200 μm or less has recently been prevailing among other ones, and some of them which have a thickness ranging from approximately 40 μm to 60 μm are also widely used. In the case of a wiring board using the core substrate with the thickness of approximately 40 μm to 60 μm, the thickness of the wiring board, including solder resist, is approximately 100 μm.

FIG. 4 is a cross-sectional view of a structure that schematically shows an example of a BGA type semiconductor package. This semiconductor package mainly includes a semiconductor chip 1, an insulative wiring board 8, a thin metal wire 7 for connecting the semiconductor chip 1 and the insulative wiring board 8, and an external connection terminal 9 made of metal.

The insulative wiring board includes an insulative core substrate, made of material such as epoxy resin, on which both surfaces a wiring pattern, made of copper foil, is provided. The wiring patterns on the both surfaces of the insulative core substrate are connected to each other through through-holes, which are formed by making holes in the insulative wiring board and then plating inner surfaces of the holes with copper.

The insulative wiring board is arranged so as to be covered with an insulative solder resist, excluding (i) a wire-bonding terminal section via which wiring bonding is carried out onto wiring that has been subjected to circuit configuration on the insulative wiring board and (ii) a land section in which external terminals are formed.

Moreover, in the BGA type semiconductor package, a semiconductor chip is mounted, by using a member such as an adhesive material, to a surface opposite to the surface, on the insulative wiring board, where the circuit is formed. A pad section provided on upper surface of the semiconductor chip is electrically connected to the wire-bonding terminal section, via a conductive thin metal wire.

The thin metal wire for an electrical connection between the semiconductor chip and the insulative wiring board is made of material such as gold or copper. The material such as metallic wire having a cross-sectional diameter ranging approximately from 20 μm to 30 μm are often employed.

High-performance electronic devices gives rise to a case in which a plurality of the semiconductor chips are stacked in the semiconductor package. In this case, the thickness of the semiconductor chip depends on the number of the semiconductor chips to be stacked. Semiconductor chips each having a thickness ranging approximately from 70 μm to 400 μm are used.

The adhesive material for attaching the semiconductor chip to the insulative wiring board may be silver paste, insulative paste, a sheet adhesive material, or the like. In particular, the sheet adhesive material is widely used in view of an improvement in adhesion between the semiconductor chip and the board.

The sheet adhesive material may be applied in advance to an area on which the semiconductor chip is to be provided in the insulative wiring board, or may be applied to the backside of the semiconductor chip. In case of applying the sheet adhesive material to the backside of the semiconductor chip, it is possible that the sheet adhesive material is applied to a back surface of wafer, and then the wafer is diced into chips. Alternatively, adhesive components of a dicing sheet may be transferred to the back surface of the semiconductor chip.

As the final step, based on a method such as a transfer molding method, the semiconductor chip and the thin metal wire are sealed with resin such as epoxy resin or biphenyl resin so as to be covered with the resin. This causes a semiconductor package to be formed.

Metallic external terminals such as solder balls are attached, by reflow, to the opposite surface of the insulative wiring board. It should be noted that the diameter of the solder balls differs depending on a factor such as a pitch of the external terminals. A material of solder has been shifted recently from a eutectic solder to a lead-free solder by taking into consideration environmental problems. Note that, since the lead-free solder has a higher melting point than the eutectic solder, it is necessary that the lead-free solder has a higher bonding temperature than the eutectic solder.

Further, there is also a solder ball terminal that has, in its center, a ball such as (i) a metallic ball made of a material such as copper or (ii) a resin ball made of a material such as resin so that a clearance between the semiconductor package and the board can be maintained above a certain value when the semiconductor package is mounted on the board.

Described above is a structure of the BGA type semiconductor package. In addition, a semiconductor package called CSP, which has a size similar to a semiconductor chip size, may have the same structure as the BGA type. In stead of a metallic ball such as solder, there are some types of semiconductor packages, i.e., (i) a semiconductor package in which external terminals are formed by applying a material such as solder paste and then melting it so that the external terminals have a size of 0.11 mm or less and (ii) a LGA type semiconductor package in which external terminals are formed only in a metal land on the board without supplying the solder.

A method for mounting each of the above semiconductor packages on the wiring board is generally carried out by mounting the semiconductor package after applying solder paste or flux to the wiring board, and then melting the external terminals made of solder with a heating device such as a reflow oven so that the semiconductor package is connected to the wiring board.

As mentioned above, a material constituting the external terminal has been shifted recently from the eutectic solder to the lead-free solder, by taking into consideration the environmental problems. This causes a tendency of a rise of a temperature applied when the semiconductor package is mounted on the wiring board. Using the lead-free solder instead of the eutectic solder causes a reflow temperature in the mounting process to increase by approximately 20° C. to 30° C.

The above method causes moisture which has been absorbed by the semiconductor package vaporizes to be vaporized and expanded due to the applied heat, so that a swell occurs in a part of the wiring board of the semiconductor package. Consequently, the semiconductor package is likely to be deformed and/or broken down.

Therefore, the semiconductor package is required to have reliability of not causing such a defect due to the applied heat. Specifically, the semiconductor package is required to have reliability of not causing defects such as deformation in outer shape, inability to mount, and/or disconnection of wirings inside because moisture which has been absorbed by the inside of the semiconductor package is vaporized and expanded in the package due to the applied heat, as shown in FIG. 5. FIG. 5 schematically shows an example of the semiconductor package in which moisture that has been absorbed by the semiconductor package is vaporized and expanded due to the applied heat.

Especially, in a semiconductor package having a thin wiring board, an area of the wiring board where the semiconductor chip is mounted is likely to swell and be broken down. This interferes with downsizing and thinning of the semiconductor package.

There are known semiconductor packages, having a structure for releasing the absorbed moisture, which address the above problem. For example, a semiconductor package of Patent Document 1 has an arrangement in which a through-hole is provided in the center of a semiconductor chip-mounting area of a wiring board, and a chip-supporting member is provided around the through-hole so as to release the absorbed moisture. There is known another semiconductor package of Patent Document 2 has an arrangement in which through-holes are provided to distribute uniformly in a semiconductor chip-mounting area of a wiring board so as to release the absorbed moisture. Moreover, there is a further semiconductor package shown in FIG. 6 has an arrangement in which through-holes 11 for releasing moisture are formed in a part of a semiconductor chip-mounting area of a wiring board so as to release the moisture in the semiconductor package. FIG. 6(a) is an overhead view of the wiring board having the through-hole 11 in a part of the semiconductor chip-mounting area. FIG. 6(b) shows a cross-section obtained when the wiring board is cut along the line B.

### (Patent Document 1)

Japanese Unexamined Patent Publication No. 2005-72498 (publication date: Mar. 17, 2005)

### (Patent Document 2)

Japanese Unexamined Patent Publication No. 2007-12714 (publication date: Jan. 18, 2007)

However, structures of Patent Documents 1 and 2 have the following problems. In the semiconductor package of Patent Document 1, an area on which the through-hole and the chip-supporting member are provided is required separately from an area for the wirings, when the wiring on the insulative wiring board is designed. Further, a margin and a clearance are also required in the insulative wiring board. Therefore, an area on which the wirings can be provided is limited because a large area on the wiring board where the wiring cannot be provided should be secured.

The semiconductor package of Patent Document 2 also has a problem that an area for the through-holes and the margin should be secured on the wiring board separately from an area for the wirings. A clearance is further required. Therefore, as is the case with the semiconductor package of Patent Document 1, the area on which the wirings can be provided is limited because the area on the wiring board where the wiring cannot be provided should be secured.

In a case where it is expressed in specific figures, when a through-hole having about 0.1 mm in diameter is provided in view of capability to deal with mass production, an area on which the wiring cannot be provided is within an area defined by a distance of about 0.3 mm from the center of the through-hole. This numerical value is obtained by the margin of (accuracy in position of the through-hole)+(distance causing solder resist not to cover the through-hole)+(distance to assure the solder resist to cover the neighboring wiring). The semiconductor package of Patent Document 1 further requires an area on which the supporting member is provided, and therefore has a wider area on which the wiring cannot be provided.

Furthermore, both of the semiconductor packages of Patent Document 1 and Patent Document 2 require a processing step for providing the through-hole(s). This causes an increase in cost of production of the wiring board.

### SUMMARY OF THE INVENTION

The present invention is accomplished in view of the problems above, and an object of the present invention is to achieve, in addition to reducing an area, in the insulative wiring board, that wirings cannot be provided, an insulative wiring board for preventing defects caused by expansion occurred due to heating of moisture absorbed by the insulative wiring board, a semiconductor package using the insulative wiring board, and a method for producing the insulative wiring board.

In view of the problems above, the insulative wiring board in accordance with the present invention is an insulative wiring board comprising: conductor layers formed on both surfaces of the board; and a mounting area where a semiconductor chip is mounted, which mounting area is provided on one of said both surfaces of the board, said both surfaces being covered with solder resist, at least one via hole in the mounting area penetrating the insulative wiring board, the conductor layers being electrically connected to each other via said at least one via hole, and the mounting area being covered with the solder resist, excluding said at least one via hole that penetrates the insulative wiring board.

Also, in view of the problems above, the method for production of the insulative wiring board in accordance with the present invention is a method for producing an insulative wiring board, comprising: forming via holes for electrically connecting conductor layers on both surfaces of the insulative wiring board; applying solder resist to the both surfaces of the insulative wiring board in which the via holes are formed; and removing the solder resist existing in at least one via hole among the via holes in a mounting area where a semiconductor chip is mounted.

With the arrangement and the method, in the insulative wiring board, the solder resist existing in at least one via hole in the semiconductor chip-mounting area is removed so that the via hole penetrates the insulative wiring board.

By means of this, it is possible to eliminate restriction on layout of the wiring on the insulative wiring board, which restriction occurs when a through-hole is additionally formed.

Moreover, since the moisture is released from the through-hole, it is also possible to prevent defects, such as a breaking down of the board, caused by vaporization and expansion occurred due to heating of moisture absorbed by the insulative wiring board.

Further, the present invention does not require a step for providing a new through-hole. Consequently, it becomes possible to reduce the time and cost for production.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 shows one embodiment of the present invention. FIG. 1(a) is a view showing a wiring pattern of an insulative wiring board. FIG. 1(b) is a view showing a cross-section obtained when cutting the wiring pattern along the line A in FIG. 1(a).

FIG. 2 is a view showing a flow of producing an insulative wiring board of the embodiment of the present invention and a flow of producing a conventional insulative wiring board.

FIG. 3(a) is a view showing one example of arrangements of through-holes in via holes. In FIG. 3(a), a through-hole is formed in each of the via holes in a semiconductor chip-mounting area.

FIG. 3(b) is a view showing one example of arrangements of a through-hole in a via hole. In FIG. 3(b), a through-hole is provided in single via hole in the center of a semiconductor chip-mounting area.

FIG. 3(c) is a view showing one example of arrangements of through-holes in via holes. In FIG. 3(c), through-holes are provided in each of four via holes at each corner of a semiconductor chip-mounting area, and a through-hole is provided in a single via hole in the center of the semiconductor chip-mounting area.

FIG. 4 is a view schematically showing a cross-section of a BGA type semiconductor package.

FIG. 5 is a view showing a semiconductor package having a defect caused by heat.

FIG. 6 is view showing a conventional structure in which through-holes for releasing moisture are provided on the insulative wiring board. FIG. 6(a) is a view showing a wiring pattern of the insulative wiring board. FIG. 6(b) is a view showing a cross-section obtained when cutting the wiring pattern along the line B in FIG. 6(a).

### DESCRIPTION OF THE EMBODIMENTS

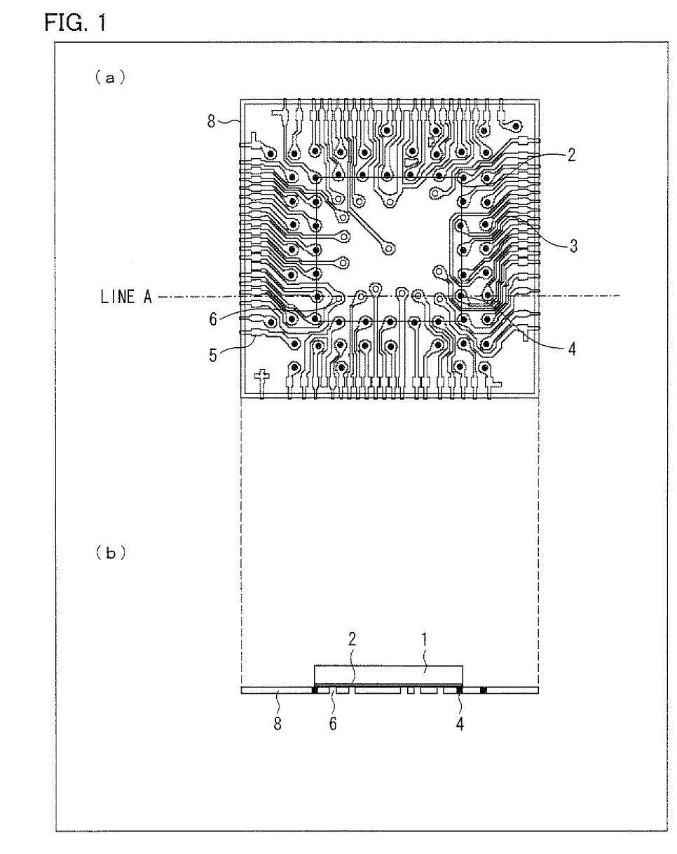

One embodiment of the present invention is described below with reference to FIGS. 1 through 3. FIG. 1(a) is a view showing a wiring pattern of an insulative wiring board 8 of the present embodiment. FIG. 1(b) is a view showing a cross-section obtained when cutting the insulative wiring board 8 on which a semiconductor chip 1 is mounted along the line A in FIG. 1(a). As shown in FIGS. 1(a) and 1(b), the insulative wiring board 8 has a semiconductor chip-mounting area 2 on which the semiconductor chip 1 is mounted, signal wiring 3 for forming the wiring pattern, via holes 4, wire-bonding terminals 5, and through-holes 6 in the respective via holes.

The semiconductor chip-mounting area 2 is an area, in the insulative wiring board 8, where the semiconductor chip 1 is mounted.

Inner surface of each of the via holes 4 is plated with copper. By means of this, the wiring pattern formed on an upper surface of the insulative wiring board 8 is electrically connected to a wiring pattern formed on a lower surface of the insulative wiring board 8.

Each of the through-holes 6 in the respective via holes is provided for releasing moisture so as to avoid that moisture which has been absorbed by a semiconductor package is vaporized and expanded during application of heat. Detailed description of the through-holes 6 in the respective via holes is described later.

The wire-bonding terminal 5 is a terminal to which a metal thin wire, that electrically connects the semiconductor chip 1 and the insulative wiring board 8, is connected.

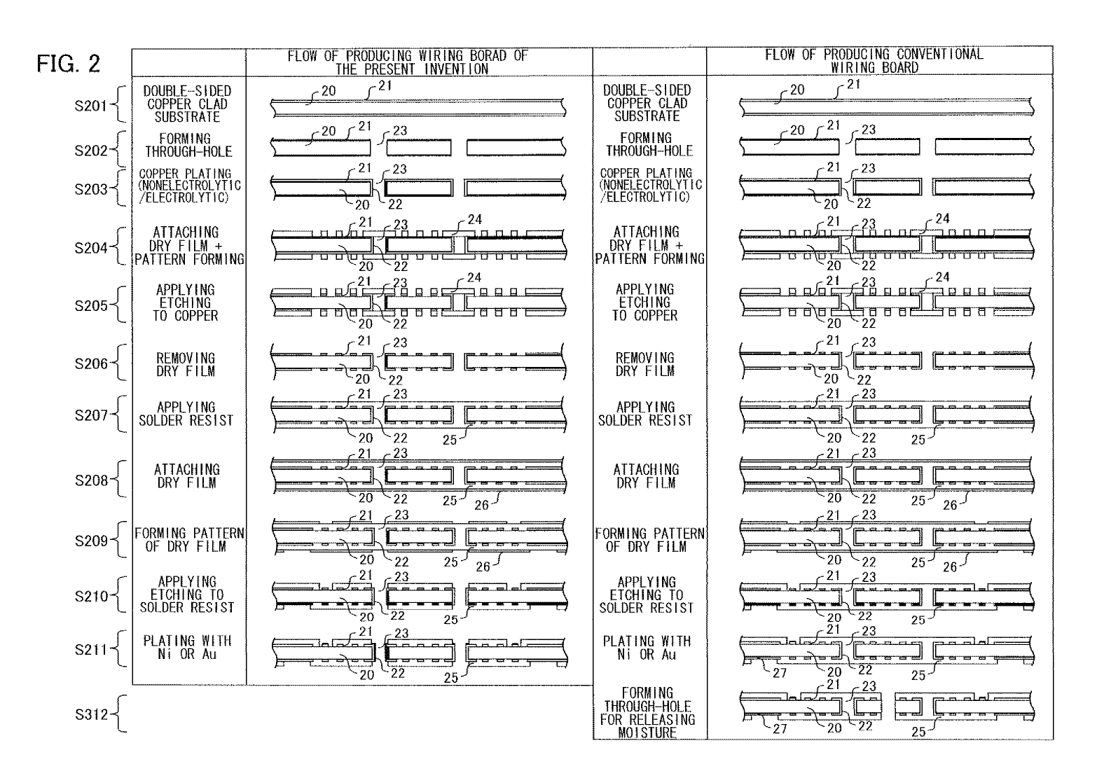

The following description deals with a method for producing an insulative wiring board 8 with reference to FIG. 2. FIG. 2 is a view showing a flow of producing a wiring board of the present embodiment and a flow of producing a conventional wiring board.

First, a double-sided copper clad substrate is used as the wiring board. The double-sided copper clad substrate is prepared by attaching copper foil 21 to both surfaces of a core substrate 20 that is obtained by impregnating glass fiber with epoxy resin (S201). A core substrate having a thickness of 0.07 mm was used in the present embodiment. Note that a core substrate having a core thickness of 0.2 mm or less has been becoming a majority in recent years.

Then, a through-hole 23 is provided so as to electrically connect an upper surface of the wiring board to a lower surface of the wiring board (S202). The through-hole may be provided by using a drill or a laser. In the present embodiment, the through hole was provided by a drill so as to have a diameter of 0.1 mm. Width of the wiring was arranged so as to be 50 μm. A gap between wires of the wiring was also arranged so as to be 50 μm. Note that a diameter of the through-hole has been developed to be smaller, and through-holes having a diameter of 0.2 mm or less have been becoming a majority in recent years.

After the through-hole 23 is provided, the inner surface of the through-hole 23 are plated with copper so that the copper foil 21 on the upper surface of the wiring board is electrically connected to the copper foil 21 on the lower surface of the wiring board (S203).

Next, dry films 24 for patterning is attached to the copper foils 21 on the upper and lower surfaces of the wiring board, respectively, and then a positioning is carried out by a mask pattern. Thereafter, an exposure is carried out, and etching is carried out with respect to the dry films 24 thus processed, thereby forming a pattern of the dry film 24 (S204).

Further, a wiring pattern is formed by applying etching to the copper foils 21 on the upper and lower surfaces of the wiring board based on the pattern of the dry film 24 (S205). Then, the dry films 24 are removed (S206).

Described above is related to how a pattern obtained from the etching of copper foil is formed based on a subtractive method, which was carried out in the present embodiment. In the present embodiment, the pattern has a thickness of approximately 15 μm. Note that a pattern having a thickness of approximately 10 μm to 20 μm is widely used.

Alternatively, the wiring board of the present invention may be a wiring board prepared by an active method (or a semi active method) in which a through-hole is provided in a board maintaining a thin layer of copper foil on an upper and lower surfaces of the board or in a board having no copper foil, and then the wiring pattern is electrically connected to inner surface of the through-hole by plating the through-hole with copper.

After removing the dry film 24, a solder resist 25 is applied to whole area of each of the upper and lower surfaces of the wiring board (S207). In the present embodiment, the solder resist 25 was applied by a screen printing. Note that the solder resist may be applied by a roll coater.

After mask patterning (S208, S209), the solder resist 25 is partly removed by a photolithographic technique (S210). Specifically, the solder resist 25 is removed in a terminal area where a wire bonding is carried out and in a land area, which is provided on the opposite surface of the terminal area, for external terminals. Concurrently, the solder resist 25 in the via hole (through-hole 23) area is removed so that a through-hole is provided in the center of the via hole.

Lastly, the wiring board is plated with Ni or Au, thereby forming a bonding pad (S211).

As described above, according to the present embodiment, it is not necessary to secure an area where the wiring cannot be provided due to a through-hole for releasing the moisture, a margin, and a clearance etc. This is because the through-hole for releasing the moisture can be prepared by use of the via hole. Further, the wiring can be arranged without limitation because restriction on layout of the wiring is eliminated. That is, degree of freedom for arrangement of the wiring increases to a large extent.

Furthermore, a step (S212) for producing the through-hole for releasing the moisture is not required in the present embodiment, unlike the conventional technique. This gives rise to an advantage in view of cost.

The following description deals with the through-hole 6 in the via hole, which is formed in the aforementioned manner below a semiconductor chip-mounting area of the wiring board. The through-hole 6 in the via hole is formed in the center of the via hole 4, by removing the solder resist in the center of the via hole 4 for electrically connecting the wiring pattern on the surface on which the semiconductor is mounted to the wiring pattern on the surface on which the external connection terminals are provided so that the moisture is not accumulated in concentrated manner below the semiconductor chip-mounting area.

More specifically, the through-hole 6 in the via hole is formed by removing the solder resist in the center of the via hole 4 formed in the semiconductor chip-mounting area 2, as shown in FIG. 1.

As is apparent from FIG. 1, in the present embodiment, the through-hole 6 in the via hole is formed in the center of the via hole 4, provided in the wiring area, that is used in an actual semiconductor package. This can avoid that the moisture is accumulated locally in the area where the semiconductor chip 1 is mounted. Therefore, it is possible to release moisture generated by heat applied when a solder ball or the semiconductor package is mounted to the wiring board. Consequently, it is possible to prevent defects such as swell occurred in the semiconductor package due to vaporization and expansion of the moisture.

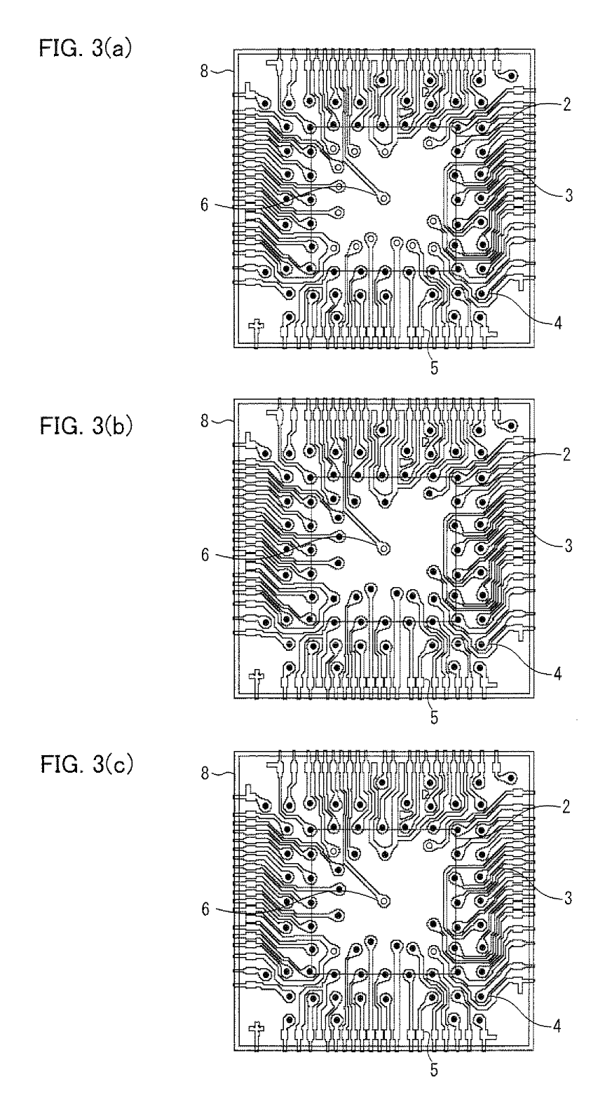

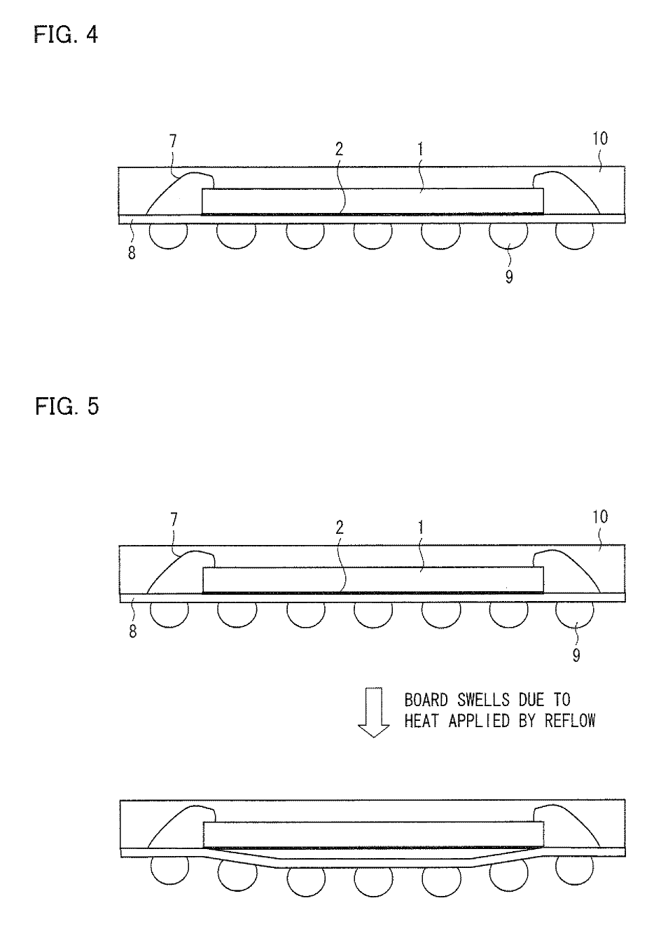

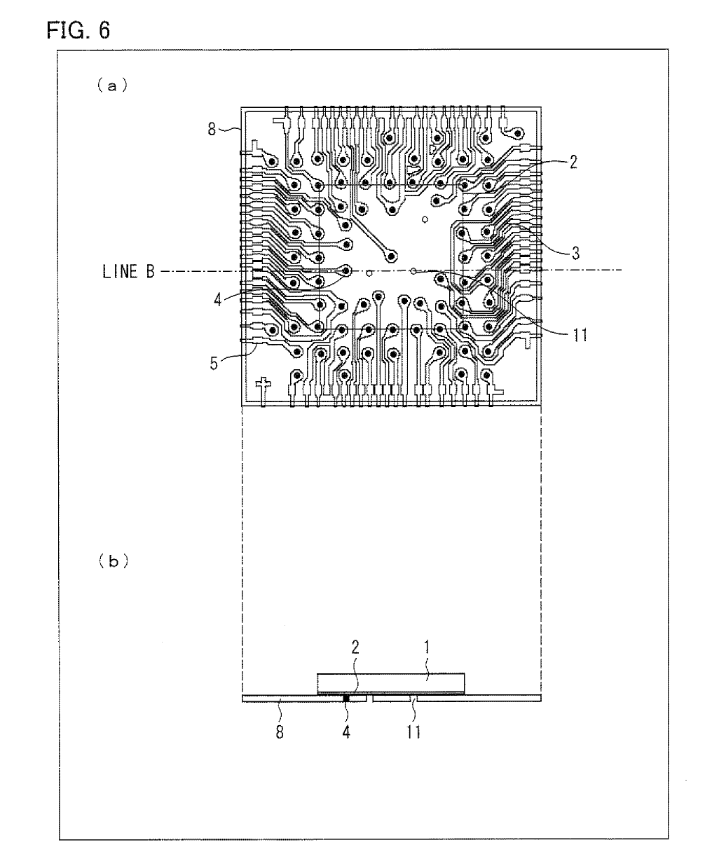

Examples of arrangements of the through-holes 6 in the via holes are shown in FIG. 3. In FIG. 3(a), a through-hole 6 is formed in each of the via holes 4 in the semiconductor chip-mounting area 2. In FIG. 3(b), a through-hole 6 is formed in a single via hole 4 in the center of the semiconductor chip-mounting area 2. In FIG. 3(c), through-holes 6 are formed in each of four via holes 4 at each corner of the semiconductor chip-mounting area 2, and a through-hole 6 is formed in a single via hole 4 in the center of the semiconductor chip-mounting area 2.

It should be noted that the arrangements of the through-holes 6 are not limited to the ones shown in FIG. 3, and the number of the through-holes 6, which are formed in the via holes 4 in the semiconductor chip-mounting area 2, is not limited to a specific one.

The larger number of the through-holes for releasing the moisture are provided, the more paths for allowing the moisture to escape during the application of heat can be secured. As a result of this, defects caused by the applied heat can be prevented more assuredly. However, the number of the through-holes is affected by a size of the semiconductor chip-mounting area 2, the number of the via holes 4 in the semiconductor chip-mounting area 2, the number of semiconductor chips to be mounted, a thickness of the board, and a wiring pattern.

It is also possible to adopt an arrangement in which one via hole 4 from which the solder resist is removed and another via hole 4 from which the solder resist is removed are connected to each other via a conduit, formed by removing the solder resist, with a width of 50 μm when the through-hole 6 in the via hole is formed. Also, it is possible to adopt an arrangement in which conduits, formed radially from the through-hole by removing the solder resist, is broadened so that the moisture is not accumulated in a concentrated manner below the semiconductor chip-mounting area 2.

It should be noted that a diameter of the through-hole of the present embodiment is arranged so as to be not more than 0.1 mm since a through-hole having a diameter of more than 0.1 mm may cause a crack of the chip due to growth in load on the chip. Therefore, it is preferable to arrange the diameter of the through-hole to be 0.1 mm or less. Current majority of a lower limit of the diameter is 0.1 mm. It is technically possible to arrange the diameter to be 0.07 mm. Note however that cost for production greatly increases by making the diameter smaller. Therefore, as described above, the through-hole of the present embodiment has a diameter of 0.1 mm.

Described below is how the semiconductor package is assembled. A semiconductor chip is mounted on the semiconductor chip-mounting area 2 of the wiring board. The semiconductor chip has a sheet adhesive material on backside of a surface on which a circuit is provided. Such a semiconductor chip is obtained by attaching the sheet adhesive material to backside of a wafer that has been polished, and then dicing the wafer together with the sheet adhesive material.

In the present embodiment, a semiconductor chip having a thickness of 0.33 mm and a sheet adhesive material having a thickness of 25 μm were used. However, the present embodiment is not limited to this.

Note that a liquid adhesive material may be used as the adhesive material. It is preferable to use a sheet adhesive material because a liquid adhesive material escapes from the through-hole.

Then, a pad section on the semiconductor chip 1 and a wire-bonding section 5 on the wiring board are connected with each other via a thin metal wire. A gold thin wire having a diameter of 25 μm was used in the present embodiment.

The semiconductor chip 1 and the thin metal wire are sealed with resin by a transfer molding method so as to be protected. The resin used as the sealing in the present embodiment was epoxy resin. After applying flux to lands for external connection terminals, which are provided on the backside of the board which has been sealed with resin, solder balls are provided on each of the lands, and then are heated and melted in a reflow oven so as to be firmly fixed to the board, thereby forming external terminals. The solder ball used in the present embodiment was a lead-free solder ball.

It should be noted that solder paste, instead of the solder ball, may be applied to lands for external terminals, and then are heated and melted in the reflow oven so that the external terminals are formed. In the case of an LGA type semiconductor package, the land for the external terminals may be, as it is, used as the external terminal. In this regard, however, solder has to be supplied to the board when the semiconductor package is mounted.

Individual semiconductor packages which have been subjected to dicing are finally provided. Thus, the assembling which is carried out with respect to the semiconductor package is completed.

As described above, the insulative wiring board in accordance with the present invention is an insulative wiring board comprising: conductor layers formed on both surfaces of the board; and a mounting area where a semiconductor chip is mounted, which mounting area is provided on one of said both surfaces of the board, said both surfaces being covered with solder resist, at least one via hole in the mounting area penetrating the insulative wiring board, the conductor layers being electrically connected to each other via said at least one via hole, and the mounting area being covered with the solder resist, excluding said at least one via hole that penetrates the insulative wiring board.

Also, the method for production of the insulative wiring board in accordance with present invention is a method for producing an insulative wiring board, comprising: forming via holes for electrically connecting conductor layers on both surfaces of the insulative wiring board; applying solder resist to the both surfaces of the insulative wiring board in which the via holes are formed; and removing the solder resist existing in at least one via hole among the via holes in a mounting area where a semiconductor chip is mounted.

With the arrangement and the method, in the insulative wiring board, the solder resist existing in at least one via hole in the semiconductor chip-mounting area is removed so that the via hole penetrates the insulative wiring board.

By means of this, it is possible to eliminate restriction on layout of the wiring on the insulative wiring board, which restriction occurs when a through-hole is additionally formed.

Moreover, since the moisture is released from the through-hole, it is also possible to prevent defects, such as a breaking down of the board, caused by vaporization and expansion occurred due to heating of moisture absorbed by the insulative wiring board.

Further, the present invention does not require a step for providing a new through-hole. Consequently, it becomes possible to reduce the time and cost for production.

The insulative wiring board in accordance with the present invention may be arranged so that at least two via holes that penetrate the insulative wiring board are formed; and the solder resist that exists between said at least two via holes is removed so that removed solder resist has a certain width.

With the arrangement, two or more via holes are connected to each other via a conduit formed by removing the solder resist.

By means of this, it is possible to prevent the moisture from accumulating in a concentrated manner below the semiconductor chip-mounting area.

The word “a certain width” may intend a width of approximately 50 μm, for example.

Further, the semiconductor package in accordance with the present invention is a semiconductor package comprising: an insulative wiring board including a mounting area; and a semiconductor chip mounted on the mounting area of the insulative wiring board, said insulative wiring board further including: conductor layers formed on both surfaces of the board, the mounting area being provided on one of said both surfaces of the board, and at least one via hole in the mounting area penetrating the insulative wiring board, the conductor layers being electrically connected to each other via said at least one via hole, said semiconductor chip being sealed with resin.

With the arrangement, in the insulative wiring board of the semiconductor package, at least one via hole in the semiconductor chip-mounting area penetrates the insulative wiring board.

By means of this, it is possible to eliminate restriction on layout of the wiring on the insulative wiring board, which restriction occurs when a through-hole is additionally formed.

Moreover, since the moisture is released from the through-hole, it is also possible to prevent defects, such as a breaking down of the board, caused by vaporization and expansion occurred due to heating of moisture absorbed by the insulative wiring board.

Further, the present invention does not require a step for providing a new through-hole. Consequently, it becomes possible to reduce the time and cost for production.

The semiconductor package in accordance with the present invention may be a semiconductor package comprising: an insulative wiring board including a mounting area; and a semiconductor chip mounted on the mounting area of the insulative wiring board, the semiconductor chip being sealed with resin.

The arrangement also attains the aforementioned effects.

The concrete embodiments and examples discussed in the foregoing detailed explanation serve solely to illustrate the technical details of the present invention, which should not be narrowly interpreted within the limits of such embodiments and examples, but rather may be applied in many variations within the spirit of the present invention and the scope of the patent claims set forth below.

What is claimed is:

1. An insulative wiring board comprising:
conductor layers formed on both surfaces of the board; and
a mounting area where a semiconductor chip is mounted, which mounting area is provided on one of said both surfaces of the board,
said both surfaces being covered with solder resist,
at least one via hole in the mounting area penetrating the insulative wiring board, the conductor layers being electrically connected to each other via said at least one via hole, and
the mounting area being covered with the solder resist, excluding said at least one via hole that penetrates the insulative wiring board.

2. The insulative wiring board according to claim 1, wherein:
at least two via holes that penetrate the insulative wiring board are formed; and
the solder resist that exists between said at least two via holes is removed so that removed solder resist has a certain width.

3. A semiconductor package comprising:
an insulative wiring board including a mounting area; and
a semiconductor chip mounted on the mounting area of the insulative wiring board,
said insulative wiring board further including:
conductor layers formed on both surfaces of the board,
the mounting area being provided on one of said both surfaces of the board, and
at least one via hole in the mounting area penetrating the insulative wiring board, the conductor layers being electrically connected to each other via said at least one via hole,
said semiconductor chip being sealed with resin.

4. A semiconductor package comprising:
an insulative wiring board including a mounting area; and
a semiconductor chip mounted on the mounting area of the insulative wiring board,
said insulative wiring board further including:
conductor layers formed on both surfaces of the board,
the mounting area being provided on one of said both surfaces of the board,
said both surfaces being covered with solder resist,
at least one via hole in the mounting area penetrating the insulative wiring board, the conductor layers being electrically connected to each other via said at least one via hole, and
the mounting area being covered with the solder resist, excluding said at least one via hole that penetrates the insulative wiring board,
said semiconductor chip being sealed with resin.

5. A semiconductor package comprising:
an insulative wiring board including a mounting area; and
a semiconductor chip mounted on the mounting area of the insulative wiring board,
said insulative wiring board further including:
conductor layers formed on both surfaces of the board,
the mounting area being provided on one of said both surfaces of the board,
said both surfaces being covered with solder resist,
at least two via holes in the mounting area penetrating the insulative wiring board, the conductor layers being electrically connected to each other via said at least two via holes, and
the mounting area being covered with the solder resist, excluding said at least two via holes that penetrate the insulative wiring board, the solder resist that exists between said at least two via holes being removed so that removed solder resist has a certain width,
said semiconductor chip being sealed with resin.

6. A method for producing an insulative wiring board, comprising:
forming via holes for electrically connecting conductor layers on both surfaces of the insulative wiring board;
applying solder resist to the both surfaces of the insulative wiring board in which the via holes are formed; and
removing the solder resist existing in at least one via hole among the via holes in a mounting area where a semiconductor chip is mounted.
